(19) United States
(12) Patent Application Publication
(10) Pub. No.: US 2014/0133735 A1
(43) Pub. Date: May 15, 2014

(54) METHOD OF INSPECTING A LEAD OF AN ELECTRIC DEVICE

(71) Applicant: KOH YOUNG TECHNOLOGY INC., Seoul (KR)

(72) Inventor: Joong-Ki JEONG, Seoul (KR)

(73) Assignee: KOH YOUNG TECHNOLOGY INC., Seoul (KR)

(21) Appl. No.: 14/073,174

(22) Filed: Nov. 6, 2013

(30) Foreign Application Priority Data
Nov. 12, 2012 (KR) 10-2012-0127236

(51) Int. Cl. G01R 31/309

(52) U.S. Cl. CPC G01R 31/309
USPC 382/147

(57) ABSTRACT

A method of inspecting leads of an electric device, which is capable of improve reliability of inspection regardless of noises induced by regions near the lead. The method uses a height or a brightness of a shoulder region of the lead to inspect existence or nonexistence or a height or a brightness of a tip region of the lead to inspect fastening or unfastening. Therefore, reliability of inspection is improved in comparison with a conventional inspection using colors of lead region.

### CROSS REFERENCE TO RELATED APPLICATION

This application claims priority from and the benefit of Korean Patent Applications No. 10-2012-0127236 filed on Nov. 12, 2012, which is hereby incorporated by reference for all purposes as if fully set forth herein.

### BACKGROUND OF THE INVENTION

1. Field of the Invention

Exemplary embodiments of the present invention relate to a method of inspecting a lead of an electric device. More particularly, exemplary embodiments of the present invention relate to a method of inspecting a lead of an electric device, through which the electric device is mounted on a printed circuit board (PCB).

2. Discussion of the Background

Generally, a plurality of electric devices is mounted on a printed circuit board. Each of the electric devices has a plurality of leads, and the leads are connected to the printed circuit board through a solder joint.

In order to inspect whether an electric device is properly mounted on the printed circuit board, existence or nonexistence of lead that is connected to a printed circuit board through solder joint is inspected.

According to a conventional method of inspecting existence or nonexistence of lead, images of lead regions are captured, and then colors of the images are compared with each other.

However, according to the conventional method, only colors of the images are used to inspect existence or nonexistence of lead, so that reliability of inspection is lowered due to color noises induced by regions near the lead.

### SUMMARY OF THE INVENTION

Exemplary embodiments of the present invention provide a method of inspecting leads of an electric device, which is capable of inspecting existence and nonexistence or fastening and unfastening of the lead exactly regardless of noises induced by regions near the lead.

According to an exemplary embodiment of the present invention, a method of inspecting leads of an electric device, through which the electric device is mounted on a printed circuit board. The method includes capturing images of lead regions of the electric device, measuring heights of interest regions of leads in the image, and determining whether each lead is existent or nonexistent by comparing heights of interest regions.

For example, determining whether each lead is existent or nonexistent may include calculating average of heights of interest regions of leads, comparing each of the heights of the interest regions of leads with the average, and determining whether each of the heights of the interest regions is within a maximum permission tolerance in comparison with the average.

For example, each of the interest regions may be a shoulder region of a lead.

According to another exemplary embodiment of the present invention, a method of inspecting leads of an electric device, through which the electric device is mounted on a printed circuit board. The method includes capturing an image of a lead region of the electric device, measuring height of interest region of the lead in the image, and determining existence and nonexistence or fastening and unfastening of the lead by determining whether heights of the interest regions are within a previously set reference height by comparing each of the heights of interest regions of leads with the previously set reference height.

For example, the reference height may be set between minimum permission height and maximum permission height of the height of the interest regions of a lead properly mounted.

In this case, each of the interest regions may be a shoulder region of a lead.

The existence of a lead is determined when the height of the shoulder region is within the reference height, and the nonexistence of a lead is determined when the height of the shoulder region is out of the reference height.

Alternatively, the reference height may be set under a maximum permission height.

In this case, the interest region may be a tip region of a lead.

The fastening of a lead is determined when a height of the tip region is under the reference height, and the unfastening of a lead is determined when a height of the tip region is higher than the reference height.

According to still another exemplary embodiment of the present invention, a method of inspecting leads of an electric device, through which the electric device is mounted on a printed circuit board. The method includes capturing images of lead regions of the electric device, measuring brightness of interest regions of leads in the images of the lead regions, and determining whether each lead is existent or nonexistent by comparing the brightness of interest regions with each other.

For example, determining whether each lead is existent or nonexistent includes calculating average of brightness of the interest regions of leads, comparing the brightness of the interest region of each lead with the average, and determining whether the brightness of the interest regions of each lead within a maximum permission tolerance.

For example, each of the interest regions may be a shoulder region of a lead.

According to still another exemplary embodiment of the present invention, a method of inspecting leads of an electric device, through which the electric device is mounted on a printed circuit board. The method includes capturing an image of a lead region of the electric device, measuring brightness of an interest region of the lead in the image of the lead region, and determining whether the lead is existent or nonexistent by comparing the brightness of the interest region with a reference brightness that is previously set.

For example, the reference brightness may be set between minimum permission brightness and maximum permission brightness of the interest region.

For example, each of the interest regions may be a shoulder region of the lead.

According to the method of inspecting leads of an electric device of the present exemplary embodiments, height or brightness of the shoulder region of the lead is measured to inspect existence or nonexistence of each lead or height of the tip region of the lead is measured to inspect fastening or unfastening of each lead, regardless of color noise induced by environment or regions near the lead. Therefore, reliability of inspection is improved.

Additional features of the invention will be set forth in the description which follows, and in part will be apparent from the description, or may be learned by practice of the invention.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a side view showing a lead connected to a printed circuit board.

FIG. 2 is a block diagram showing a method of inspecting a lead of an electric device according to a first exemplary embodiment of the present invention.

FIG. 3 is a block diagram showing determining of existence or nonexistence of lead according to the first exemplary embodiment of the present invention.

FIG. 4 is a block diagram showing a method of inspecting a lead of an electric device according to a second exemplary embodiment of the present invention.

FIG. 5 is a block diagram showing a method of inspecting a lead of an electric device according to a third exemplary embodiment of the present invention.

FIG. 6 is a block diagram showing a method of inspecting a lead of an electric device according to a fourth exemplary embodiment of the present invention.

FIG. 7 is a block diagram showing determining of existence or nonexistence of lead according to the fourth exemplary embodiment of the present invention.

FIG. 8 is a block diagram showing a method of inspecting a lead of an electric device according to a fifth exemplary embodiment of the present invention.

### DETAILED DESCRIPTION OF THE ILLUSTRATED EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be described in detail with reference to the accompanying drawings.

### Embodiment 1

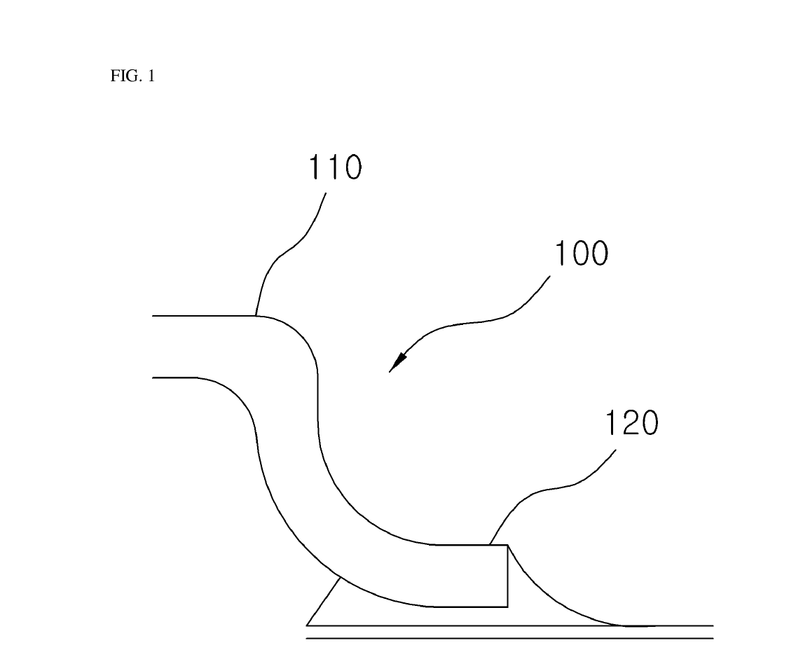

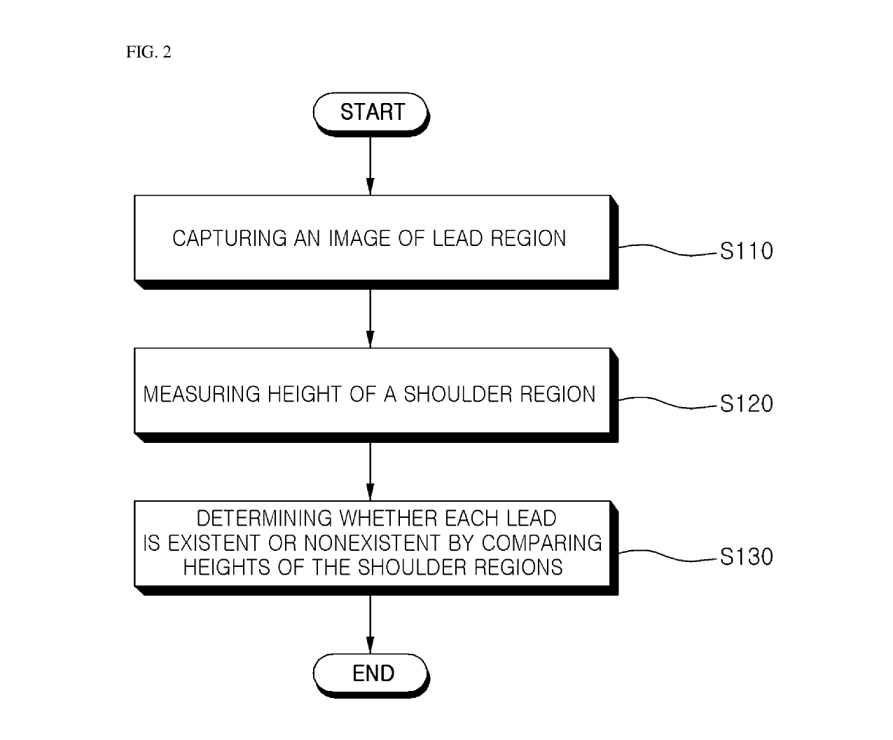

FIG. 1 is a side view showing a lead connected to a printed circuit board, and FIG. 2 is a block diagram showing a method of inspecting a lead of an electric device according to a first exemplary embodiment of the present invention.

Referring to FIG. 1 and FIG. 2, the first exemplary embodiment of the present invention relates to a method of inspecting existence or nonexistence of a lead 100 of an electric device. According to the method, the heights of interest regions of each lead 100 is measured to inspect existence or nonexistence of the lead 100, so that reliability of inspection is improved regardless of environmental regions near the lead 100.

In order to inspect the lead in accordance with the first exemplary embodiment of the present invention, an image of a lead region where a lead 100 of an electric device is supposed to be disposed is captured by a camera (not shown) (step S110).

After capturing the image of the lead region, a height of an interest region of each lead 100 is measured through the captured image by a control section (not shown) (step S120).

In this embodiment, it is preferable that the interest region is set to be a shoulder region 110 of the lead 100, since the present embodiment is relates to a method of inspecting existence or nonexistence of the lead.

As described above, when the height of the shoulder region 110 of each lead 110 is measured through the captured image, the heights of the shoulder regions 110 of leads 110 are compared with each other to inspect existence or nonexistence of each lead 110 (step S130).

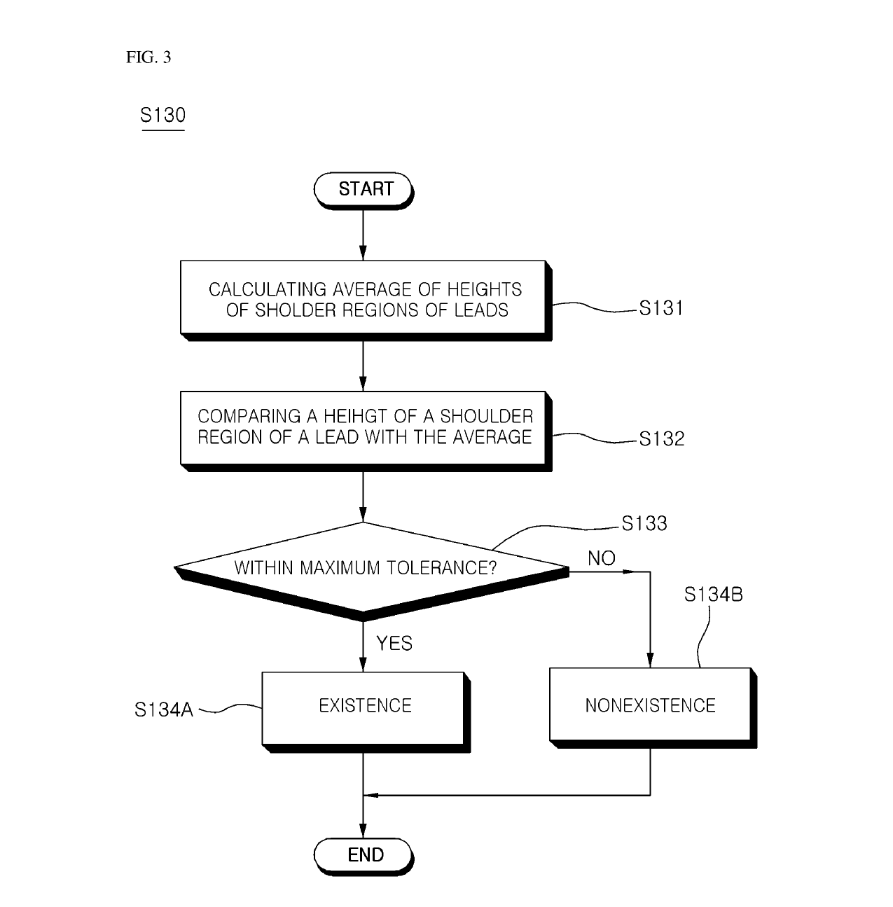

Referring to FIG. 3, determining of existence or nonexistence of lead (step S130) will be described in detail.

FIG. 3 is a block diagram showing determining of existence or nonexistence of lead according to the first exemplary embodiment of the present invention.

Referring to FIG. 3, in order to compare the heights of the shoulder regions 110, which corresponds to the interest region, of the leads 100, average of the heights of the shoulder regions 110 of the leads 100 is calculated by the control section (not shown) (step S131).

When the average of the heights of the shoulder regions 110 of the leads 100 is calculated, a height of a shoulder region 110 of a lead 100 is compared with the average (step S132).

After comparing the height of the shoulder region 110 of the lead 100 with the average, the height of the shoulder region 110 of the lead 100 is determined whether the height of the shoulder region 110 of the lead 100 is within a maximum permission tolerance (step S133) to determine whether each lead is existent (step S134A) or nonexistent (step S134B).

That is, the control section determines existence of the lead 100 if the height of the shoulder region 110 of the lead 100 is within the maximum permission tolerance, and nonexistence of the lead 100 if the height of the shoulder region 110 of the lead 100 is out of the maximum permission tolerance.

### Embodiment 2

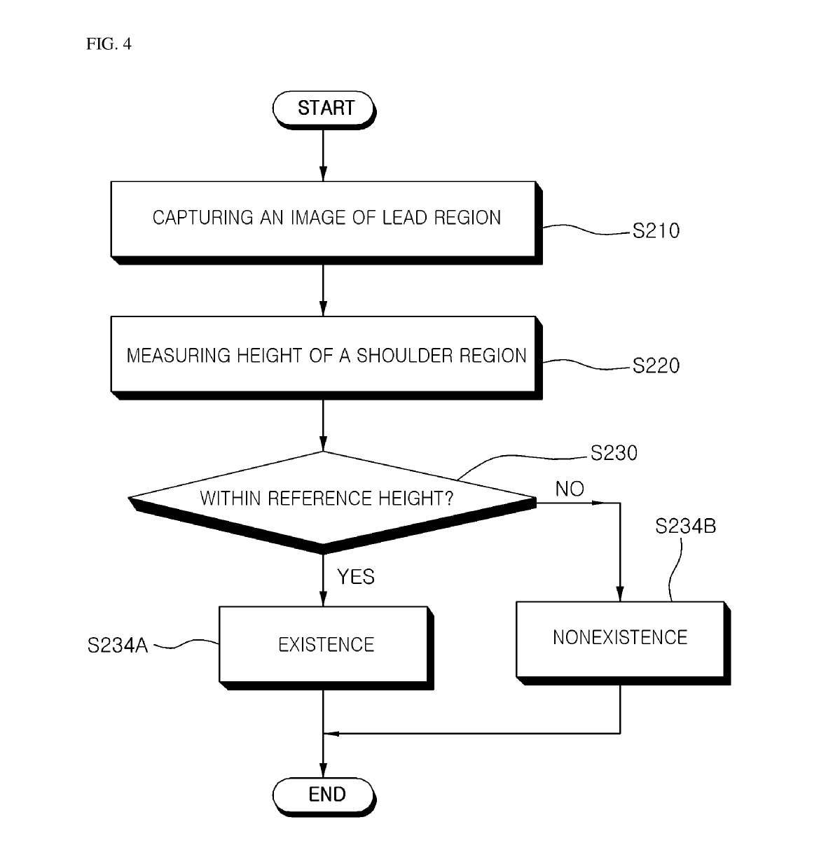

FIG. 4 is a block diagram showing a method of inspecting a lead of an electric device according to a second exemplary embodiment of the present invention.

The method of inspecting a lead of an electric device according to the present embodiment is substantially same as the first exemplary embodiment except for a step of determining existence or nonexistence of a lead (step S230) by using the height of the interest region of a lead. Thus, explanation of other steps except for the step of determining existence or nonexistence of a lead by using the height of the interest regions of the lead will be omitted.

The present embodiment is also relates to a method of inspecting existence or nonexistence of a lead. Therefore, it is preferable to set the interest region at the shoulder region 110 of leads 100.

Referring to FIG. 1 and FIG. 4, a height of a shoulder region 110 of a lead 100 is compared with a reference height that is previously set by a control section (not shown), and then the height of the shoulder region 110 of the lead 100 is determined whether the height of the shoulder region 110 of the lead 100 is within the reference height (step S230) to determine whether each lead 100 is existent (step S234A) or nonexistent (step S234B).

That is, the control section determines existence of the lead 100 if the height of the shoulder region 110 of the lead 100 is within the reference height (step S234A), and nonexistence of the lead 100 if height of the shoulder region 110 of the lead 100 is out of the reference height (step S234B).

In this case, the reference height has a range between a minimum permission height and a maximum permission height.

### Embodiment 3

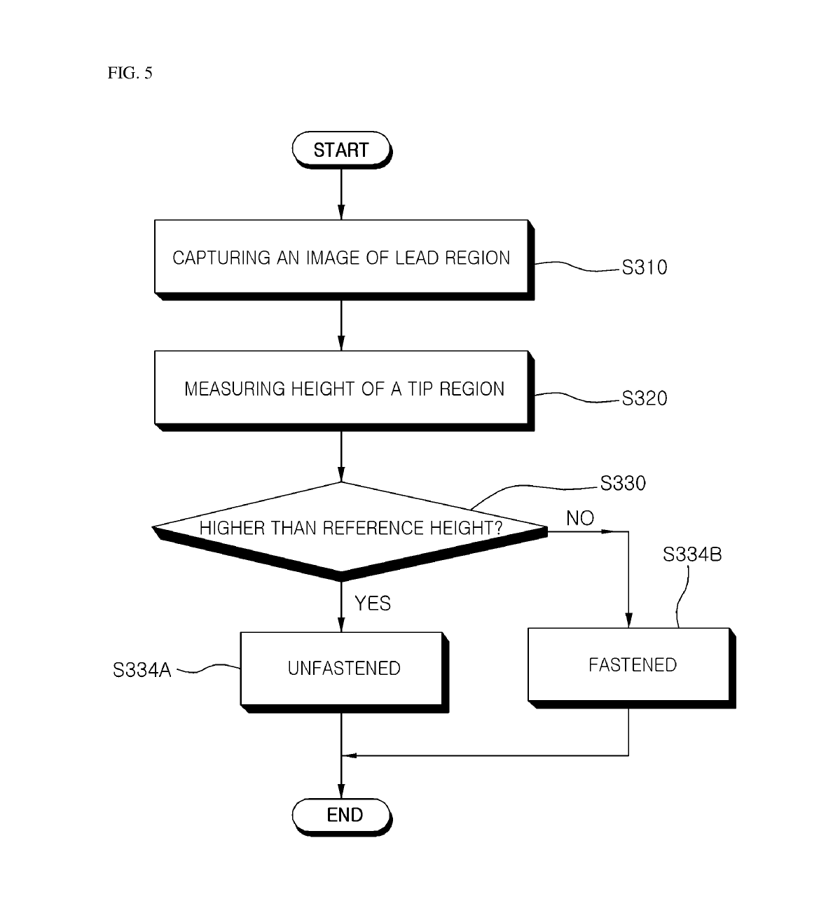

FIG. 5 is a block diagram showing a method of inspecting a lead of an electric device according to a third exemplary embodiment of the present invention.

The method of inspecting a lead of an electric device according to the present embodiment is substantially same as the second exemplary embodiment except for a step of determining fastening or unfastening of a lead by using heights of interest regions of leads (step S330). Thus, explanation of other steps except for the step of determining fastening or unfastening of a lead by using heights of interest regions of leads will be omitted.

The present embodiment is also relates to a method of inspecting fastening or unfastening of a lead. Therefore, it is preferable to set the interest region at a tip region 120 of leads 100.

Referring to FIG. 1 and FIG. 5, in the method of inspecting a lead according to the present embodiment, a control section (not shown) compares a height of tip region 120 of a lead 100 with a reference height to determine whether the height of the tip region 120 is within a reference height (step S330), and then unfastening (step S334A) or fastening (step S334B) of the lead 100 is determined.

That is, the control section determines fastening of the lead 100 if the height of the tip region 120 of the lead 100 is lower than the reference height (step S334B), and unfastening of the lead 100 if height of the tip region 120 of the lead 100 is higher than the reference height (step S334A).

In this case, the reference height is preferably set under a maximum permission height of tip region 120 of a lead 120.

### Embodiment 4

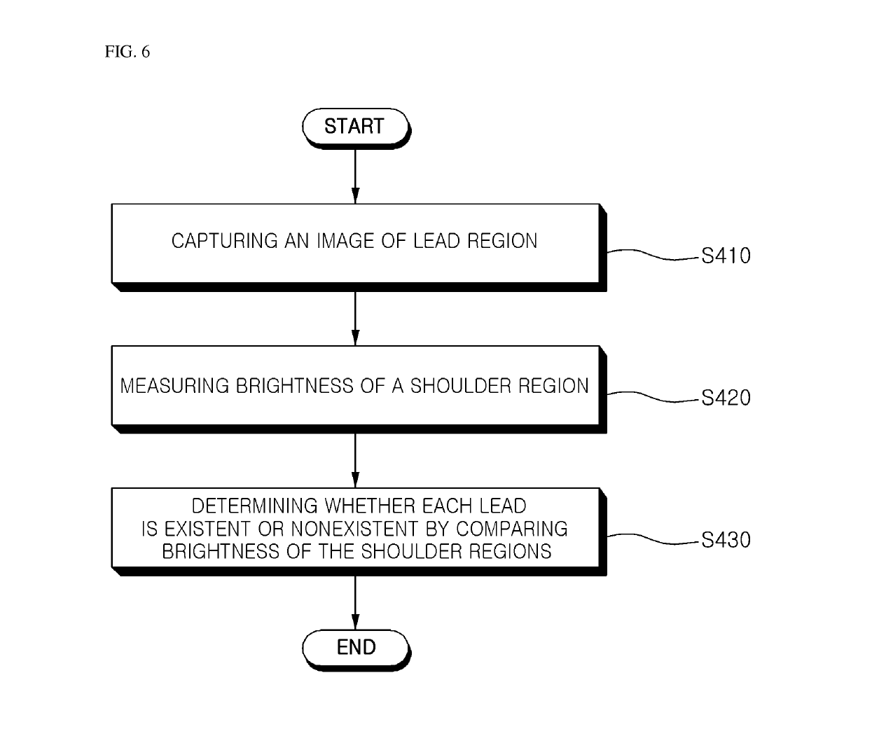

FIG. 6 is a block diagram showing a method of inspecting a lead of an electric device according to a fourth exemplary embodiment of the present invention.

Referring to FIG. 1 and FIG. 6, the fourth exemplary embodiment of the present invention relates to a method of inspecting existence or nonexistence of a lead 100 of an electric device. According to the method, the brightness of interest regions of each lead 100 is measured to inspect existence or nonexistence of the lead 100, so that reliability of inspection is improved regardless of environmental regions near the lead 100.

In order to inspect the lead in accordance with the fourth exemplary embodiment of the present invention, an image of a lead region where a lead 100 of an electric device is supposed to be disposed is captured by a camera (not shown) (step S410).

After capturing the image of the lead region, a brightness of an interest region of each lead 100 is measured through the captured image by a control section (not shown) (step S420).

In this embodiment, it is preferable that the interest region is set to be a shoulder region 110 of the lead 100, since the present embodiment is relates to a method of inspecting existence or nonexistence of the lead.

As described above, when the brightness of the shoulder region 110 of each lead 110 is measured through the captured image, the brightness of the shoulder regions 110 of leads 110 are compared with each other to inspect existence or nonexistence of each lead 110 (step S430).

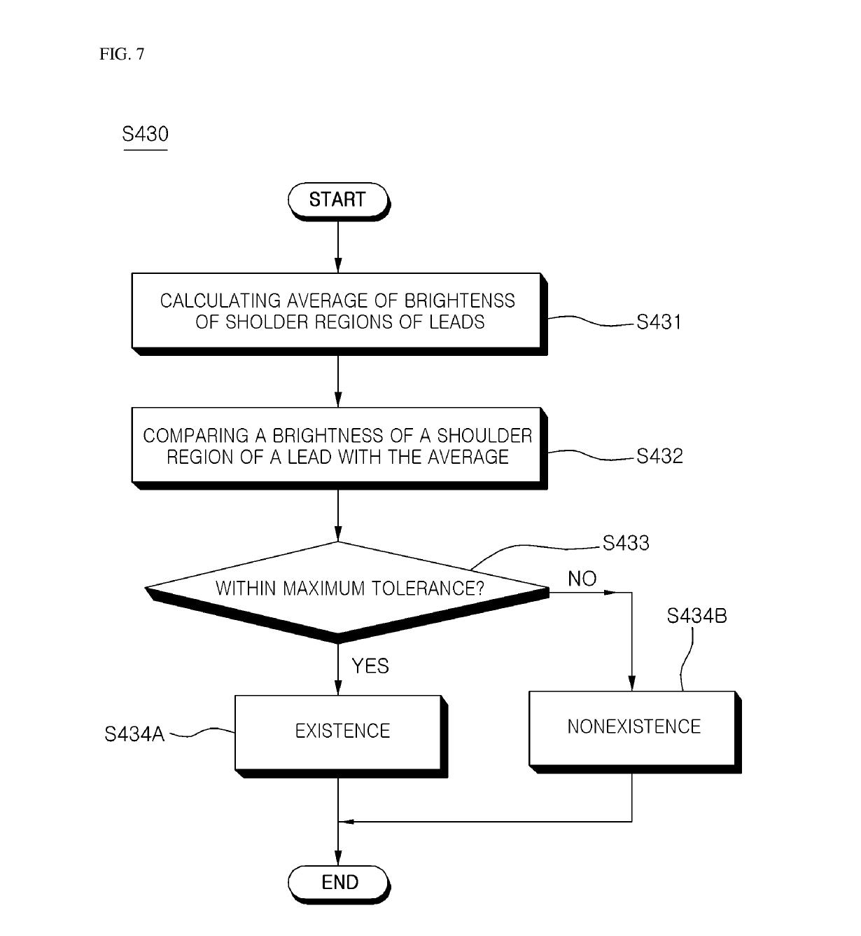

Referring to FIG. 7, determining of existence or nonexistence of lead (step S430) will be described in detail.

FIG. 7 is a block diagram showing determining of existence or nonexistence of lead according to the fourth exemplary embodiment of the present invention.

Referring to FIG. 7, in order to compare the brightness of the shoulder regions 110, which corresponds to the interest region, of the leads 100, average of the brightness of the shoulder regions 110 of the leads 100 is calculated by the control section (not shown) (step S431).

When the average of the brightness of the shoulder regions 110 of the leads 100 is calculated, a brightness of a shoulder region 110 of a lead 100 is compared with the average (step S432).

After comparing the brightness of the shoulder region 110 of the lead 100 with the average, the brightness of the shoulder region 110 of the lead 100 is determined whether the brightness of the shoulder region 110 of the lead 100 is within a maximum permission tolerance (step S433) to determine whether each lead is existent (step S434A) or nonexistent (step S434B).

That is, the control section determines existence of the lead 100 if the brightness of the shoulder region 110 of the lead 100 is within the maximum permission tolerance, and nonexistence of the lead 100 if the brightness of the shoulder region 110 of the lead 100 is out of the maximum permission tolerance.

### Embodiment 5

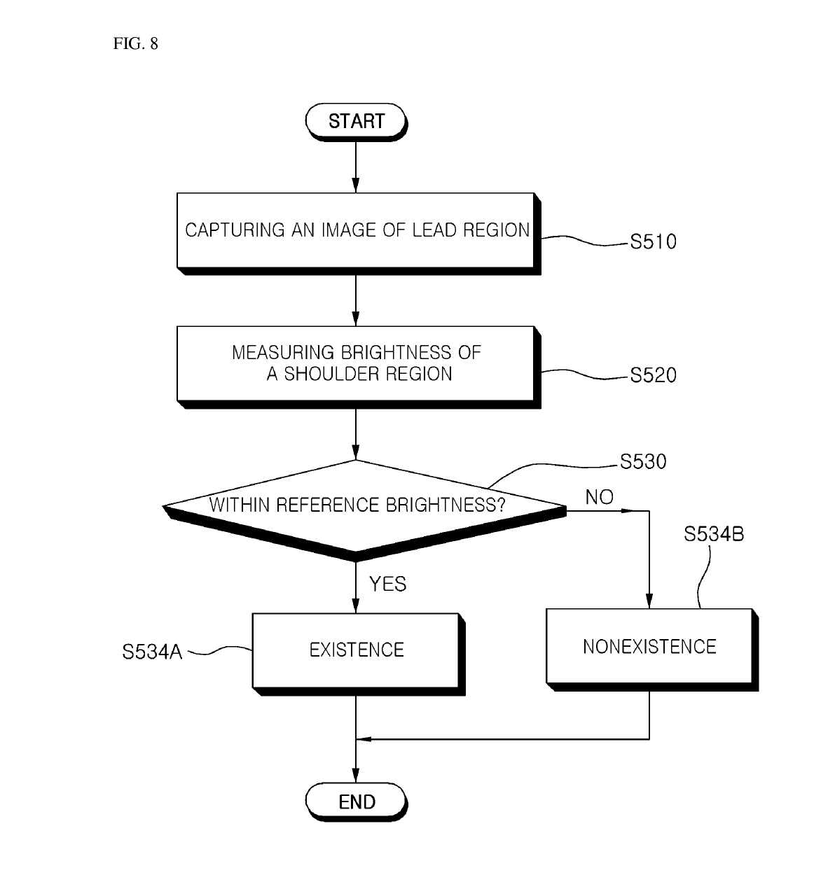

FIG. 8 is a block diagram showing a method of inspecting a lead of an electric device according to a fifth exemplary embodiment of the present invention.

The method of inspecting a lead of an electric device according to the present embodiment is substantially same as the fourth exemplary embodiment except for a step of determining existence or nonexistence of a lead (step S530) by using brightness of the interest region of a lead. Thus, explanation of other steps except for the step of determining existence or nonexistence of a lead by using the brightness of the interest region of a lead will be omitted.

The present embodiment is also relates to a method of inspecting existence or nonexistence of a lead. Therefore, it is preferable to set the interest region at the shoulder region 110 of leads 100.

Referring to FIG. 1 and FIG. 8, a brightness of a shoulder region 110 of a lead 100 is compared with a reference brightness that is previously set by a control section (not shown), and then the brightness of the shoulder region 110 of the lead 100 is determined whether the brightness of the shoulder region 110 of the lead 100 is within the reference brightness (step S530) to determine whether each lead 100 is existent (step S534A) or nonexistent (step S534B).

That is, the control section determines existence of the lead 100 if the brightness of the shoulder region 110 of the lead 100 is within the reference brightness (step S534A), and nonexistence of the lead 100 if height of the shoulder region 110 of the lead 100 is out of the reference brightness (step S534B).

In this case, the reference height has a range between a minimum permission brightness and a maximum permission brightness.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A method of inspecting leads of an electric device, through which the electric device is mounted on a printed circuit board, the method comprising:
capturing images of lead regions of the electric device;
measuring heights of interest regions of leads in the image; and
determining whether each lead is existent or nonexistent by comparing heights of interest regions.

2. The method of claim 1, wherein determining whether each lead is existent or nonexistent comprises:
calculating average of heights of interest regions of leads;
comparing each of the heights of the interest regions of leads with the average; and
determining whether each of the heights of the interest regions is within a maximum permission tolerance in comparison with the average.

3. The method of claim 2, wherein each of the interest regions is a shoulder region of a lead.

4. A method of inspecting leads of an electric device, through which the electric device is mounted on a printed circuit board, the method comprising:
capturing an image of a lead region of the electric device;
measuring height of interest region of the lead in the image; and
determining existence and nonexistence or fastening and unfastening of the lead by determining whether heights of the interest regions are within a previously set reference height by comparing each of the heights of interest regions of leads with the previously set reference height.

5. The method of claim 4, wherein the reference height is set between minimum permission height and maximum permission height of the height of the interest regions of a lead properly mounted.

6. The method of claim 5, wherein each of the interest regions is a shoulder region of a lead.

7. The method of claim 6, wherein the existence of a lead is determined when the height of the shoulder region is within the reference height, and
wherein the nonexistence of a lead is determined when the height of the shoulder region is out of the reference height.

8. The method of claim 4, wherein the reference height is set under a maximum permission height.

9. The method of claim 8, wherein the interest region is a tip region of a lead.

10. The method of claim 9, wherein the fastening of a lead is determined when a height of the tip region is under the reference height, and
wherein the unfastening of a lead is determined when a height of the tip region is higher than the reference height.

11. A method of inspecting leads of an electric device, through which the electric device is mounted on a printed circuit board, the method comprising:
capturing images of lead regions of the electric device;
measuring brightness of interest regions of leads in the images of the lead regions; and
determining whether each lead is existent or nonexistent by comparing the brightness of interest regions with each other.

12. The method of claim 11, wherein determining whether each lead is existent or nonexistent, comprises:
calculating average of brightness of the interest regions of leads;
comparing the brightness of the interest region of each lead with the average; and
determining whether the brightness of the interest regions of each lead within a maximum permission tolerance.

13. The method of claim 12, wherein each of the interest regions is a shoulder region of a lead.

14. A method of inspecting leads of an electric device, through which the electric device is mounted on a printed circuit board, the method comprising:
capturing an image of a lead region of the electric device;
measuring brightness of an interest region of the lead in the image of the lead region; and
determining whether the lead is existent or nonexistent by comparing the brightness of the interest region with a reference brightness that is previously set.

15. The method of claim 14, wherein the reference brightness is set between minimum permission brightness and maximum permission brightness of the interest region.

16. The method of claim 15, wherein each of the interest regions is a shoulder region of the lead.
